(19) United States
(12) Patent Application Publication
(10) Pub. No.: US 2022/0190151 A1
(43) Pub. Date: Jun. 16, 2022

(54) SEMICONDUCTOR DEVICE AND PRODUCING METHOD THEREOF

(71) Applicant: FUJITSU LIMITED, Kawasaki-shi (JP)

(72) Inventors: Shirou Ozaki, Yamato (JP); Junji Kotani, Atsugi (JP)

(73) Assignee: FUJITSU LIMITED, Kawasaki-shi (JP)

(21) Appl. No.: 17/481,348

(22) Filed: Sep. 22, 2021

(30) Foreign Application Priority Data
Dec. 11, 2020 (JP) 2020-206150

(51) Int. Cl. H01L 29/778; H01L 29/66; H01L 29/06

(52) U.S. Cl. CPC H01L 29/7786; H01L 29/0653; H01L 29/66462

(57) ABSTRACT

A semiconductor device is provided. In particular, a semiconductor device is disclosed as including an electron transit layer; an electron supply layer disposed on or above the electron transit layer, the electron supply layer inducing a two-dimensional electron gas in the electron transit layer; a source electrode disposed on or above the electron supply layer; a drain electrode disposed on or above the electron supply layer; a gate electrode between the source electrode and the drain electrode; and an insulating film that is disposed in a region between the gate electrode and the drain electrode, and the region being closer to the gate electrode than to the drain electrode. The insulating film includes a nitrosyl group.

### CROSS-REFERENCE TO RELATED APPLICATION

This application is based upon and claims the benefit of priority of the prior Japanese Patent Application No. 2020-206150, filed on Dec. 11, 2020, the entire contents of which are incorporated herein by reference.

### FIELD

The embodiments discussed herein are related to a semiconductor device and a producing method thereof.

### BACKGROUND

High breakdown fields and high saturated electron velocities characterize nitride semiconductors represented by GaN. These characteristics are being exploited to develop high power semiconductor devices that can operate at high voltages. Specifically, high electron mobility transistors (HEMTs) that include nitride semiconductors are being developed (see for instance Japanese Laid-open Patent Publication Nos. 2019-33200 and 2011-171440).

Herein HEMTs having an electron transit layer of GaN and an electron supply layer of AlGaN are one type of nitride semiconductor HEMTs (i.e., HEMTs that include nitride semiconductors) being most actively developed. Lattice strain occurs in the electron supply layer of the nitride semiconductor HEMT on account of the difference in lattice constants between GaN and AlGaN. Two-dimensional electron gas is induced in the electron transit layer as a result of piezoelectric polarization and spontaneous polarization of the electron supply layer, the piezoelectric polarization being generated by the lattice strain.

A gate electrode is disposed on or above the electron supply layer. In the specification, the wording “on or above” refers to “in contact with or separate from”. In order to suppress leakage current flowing through the gate electrode of a nitride semiconductor HEMT, a technique has been proposed that involves arranging a polarized layer of aluminum oxide between the gate electrode and the drain electrode (see for instance Japanese Laid-open Patent Publication No. 2019-33200). A further technique has been proposed that involves forming a gate electrode on an insulating film of SiO₂, AON or the like (see for instance Japanese Laid-open Patent Publication No. 2011-171440).

### SUMMARY

According to an aspect of the embodiments, a semiconductor device includes: an electron transit layer; an electron supply layer disposed on or above the electron transit layer, the electron supply layer inducing a two-dimensional electron gas in the electron transit layer; a source electrode disposed on or above the electron supply layer; a drain electrode disposed on or above the electron supply layer; a gate electrode disposed on or above the electron supply layer, the gate electrode being positioned between the source electrode and the drain electrode; and an insulating film that includes a nitrosyl group, the insulating film being disposed in a region that is positioned on or above the electron supply layer and between the gate electrode and the drain electrode, and the region being closer to the gate electrode than to the drain electrode.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an example of a plan-view diagram of a semiconductor device 2 of an embodiment.

FIG. 2 is a cross-sectional diagram of the semiconductor device 2 along line II-II in FIG. 1.

FIG. 3 and FIG. 4 are cross-sectional diagrams of samples for checking drops in two-dimensional electron gas density.

FIG. 5 is a diagram for explaining the operation of the semiconductor device 2.

FIG. 6 illustrates an example of a band diagram of the semiconductor device 2 at a gate edge region positioned below an overhang portion at which the gate upper portion 20 juts from the gate lower portion 16.

FIG. 7 is a diagram illustrating the influence that the type of insulating film disposed on or above the electron supply layer 6 exerts on the sheet resistance of the electron transit layer 4.

FIGS. 8A to 12B are cross-sectional diagrams illustrating an example of a production method of the semiconductor device 2 in an embodiment.

FIGS. 13 to 15 are diagrams illustrating an example of a procedure for forming the nitrosyl-oxynitride film 44.

### DESCRIPTION OF EMBODIMENTS

The embodiments will be described hereinafter according to the drawings. However, it is noted that the technical scope is not limited to the embodiments described below but covers the matters described in the claims and the equivalents thereof. Here, identical symbols are given to corresponding parts even in different drawings, and the description thereof will be omitted.

As described previously, nitride semiconductor HEMTs, which can operate at high power, are being developed. Higher output in a nitride semiconductor HEMT is achieved by increasing the output current and increasing the withstand voltage of the device. The increase in output current is realized by increasing a two-dimensional electron gas density (i.e., electron density in the two-dimensional electron gas) of the electron transit layer. When the two-dimensional electron gas density is increased, however, a strong electric field arises between the electron transit layer and the edge of the gate electrode on the drain electrode side (hereafter referred to as drain-side gate edge) upon application of voltage to the gate electrode, and avalanche breakdown becomes likelier. As a result, a great current flows in the vicinity of the drain-side gate edge, and the electron supply layer and so on is destroyed. That is, the withstand voltage drops when the two-dimensional electron gas density of the electron transit layer is increased.

The strong electric field arising between the drain-side gate edge and the electron transit layer can be suppressed by arranging a negatively charged insulating film (for instance, an alumina film having excess oxygen) in the vicinity of the drain-side gate edge. Inducement of the two-dimensional electron gas is suppressed when a negatively charged insulating film is disposed on or above the electron supply layer, and thereby electric field concentration (i.e., generation of a strong electric field) at the drain-side gate edge is mitigated.

The negative charge of the insulating film is generated for instance when electrons are captured by dangling bonds in the insulating film. However, the number of the dangling bonds easily drops on account of a manufacturing process involving heating after formation of the insulating film, because dangling bonds are active. In consequence, the negative charge of the insulating film in a finished device is not uniform, and also the amount of negative charge is insufficient. It is therefore difficult to improve the withstand voltage of a nitride semiconductor HEMT with favorable reproducibility.

According to embodiments described below, the withstand voltages of HEMTs that includes nitride semiconductors are improved with favorable reproducibility.

(1) Structure

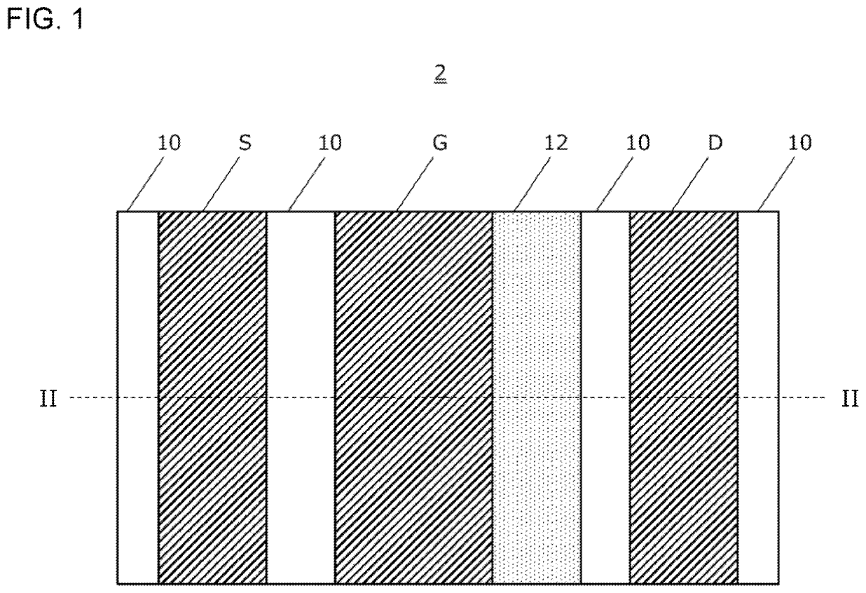

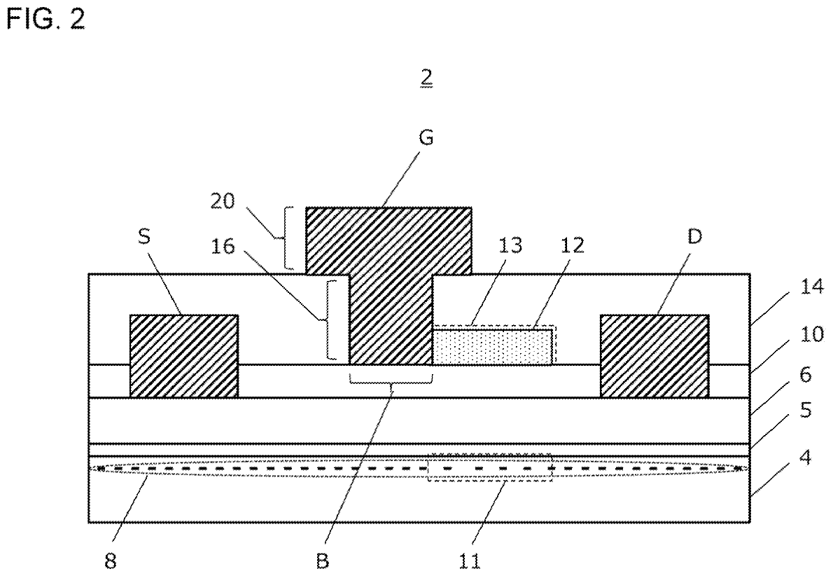

FIG. 1 is an example of a plan-view diagram of a semiconductor device 2 of an embodiment. FIG. 2 is a cross-sectional diagram of the semiconductor device 2 along line II-II in FIG. 1. FIG. 1 illustrates the planar structure of the semiconductor device 2 as viewed through a passivation film 14 (see FIG. 2). The semiconductor device 2 is a high electron mobility transistor.

Electron Transit Layer 4 and Electron Supply Layer 6

As illustrated in FIG. 2, the semiconductor device 2 has an electron transit layer 4 (so-called channel layer), and an electron supply layer 6 disposed on or above the electron transit layer 4. The electron supply layer 6 induces a two-dimensional electron gas 8 in the electron transit layer 4. In the example illustrated in in FIG. 2, a spacer layer 5 is arranged between the electron transit layer 4 and the electron supply layer 6. However, the spacer layer 5 may be omitted.

The electron transit layer 4 is, for instance, of semi-insulating GaN (hereafter referred to as i-type GaN). The electron supply layer 6 is, for instance, of n-type AlGaN. The spacer layer 5 is, for instance, of semi-insulating AlGaN (hereafter referred to as i-type AlGaN).

The two-dimensional electron gas 8 is induced in the electron transit layer 4 on account of the polarization and n-type impurity in the electron supply layer 6. The electron supply layer 6 may be of i-type AlGaN. In this case, the two-dimensional electron gas 8 is induced through polarization of the electron supply layer 6.

When the Al composition of the electron supply layer 6 (herein n-type AlGaN) is increased, lattice strain in the electron supply layer 6 increases, and the piezoelectric polarization of the electron supply layer 6 becomes great. The electron density (i.e., two-dimensional electron gas density) of the two-dimensional electron gas 8 increases as a result. Two-dimensional electron gas density increases also through an increase in the dopant concentration of the electron supply layer 6. As a result of an increase of the two-dimensional electron gas density, current that flows in the semiconductor device 2 becomes great.

Source Electrode S, Drain Electrode D and Gate Electrode G

The semiconductor device 2 further includes a source electrode S disposed on or above the electron supply layer 6 and a drain electrode D disposed on or above the electron supply layer 6. The semiconductor device 2 further includes a cap layer 10 disposed on or above the electron supply layer 6 and a gate electrode G disposed above electron supply layer 6 across the cap layer 10, the gate electrode being positioned between the source electrode S and the drain electrode D.

Nitrosyl Insulating Film 12

The semiconductor device 2 further includes an insulating film 12 disposed in a region 13 that is positioned on or above the electron supply layer 6 and between the gate electrode G and the drain electrode D. The region 13 is closer to the gate electrode G than to the drain electrode D (i.e., in a region the center whereof is closer to the gate electrode G than to the drain electrode D).

The insulating film 12 (hereafter referred to as nitrosyl insulating film) is an insulating film that includes nitrosyl groups (i.e., —N═O). Nitrosyl groups can be detected for instance by infrared absorption spectroscopy. In the example illustrated in FIG. 2, the nitrosyl insulating film 12 and the gate electrode G are disposed on the cap layer 10. However, the cap layer 10 may be omitted, and the nitrosyl insulating film 12 and the gate electrode G may be disposed directly on the electron supply layer 6.

Preferably, the nitrosyl insulating film 12 may be of aluminum oxynitride that contains (in other words, includes) nitrosyl groups. The nitrosyl insulating film 12 is disposed so as to suppress the inducement of the two-dimensional electron gas 8, which is caused by the electron supply layer 6, at a portion 11 (hereafter referred to as gate connection region) of the electron transit layer 4, the portion touching the bottom B of the gate electrode G in a plan view.

When the nitrosyl insulating film 12 is disposed on or above the electron supply layer 6, the two-dimensional electron gas density decreases (i.e., the inducement of the two-dimensional electron gas is suppressed) in a portion of the electron transit layer 4 and in the periphery of that portion, the portion being covered with the nitrosyl insulating film 12. Therefore, inducement of the two-dimensional electron gas 8 in the gate connection region 11 of the electron transit layer can be suppressed by arranging the nitrosyl insulating film 12 so as to be in contact with the gate electrode G or be close to the gate electrode G. Preferably, the nitrosyl insulating film 12 is arranged so as to be in contact with the gate electrode G, but may be arranged so as to be spaced from the gate electrode G.

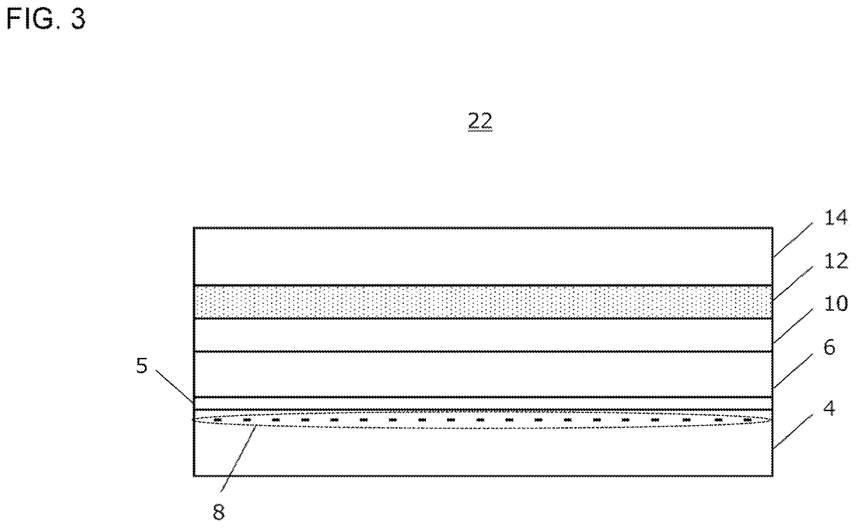

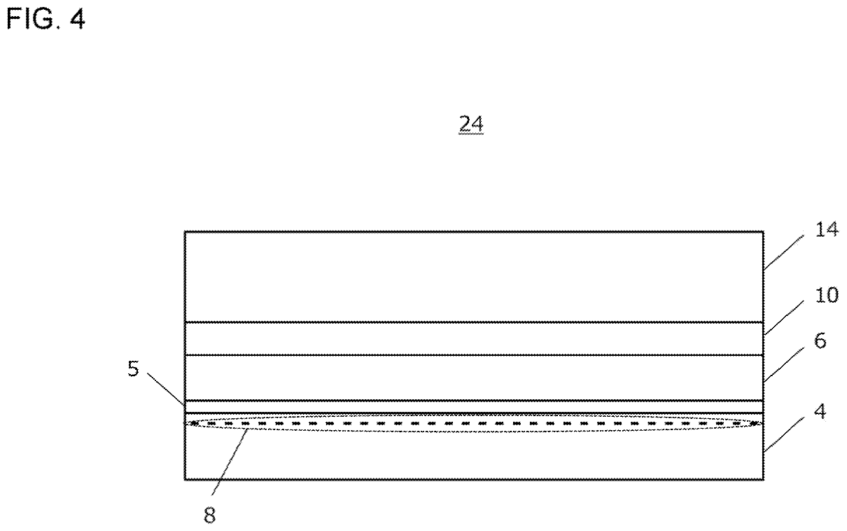

The decrease in two-dimensional electron gas density derived from the nitrosyl insulating film 12 can be ascertained by measuring the sheet resistance of the electron transit layer 4. FIG. 3 and FIG. 4 are cross-sectional diagrams of samples for checking drops in two-dimensional electron gas density. FIG. 3 illustrates a cross-sectional diagram of a sample 22 in which every layer of the semiconductor device 2 (i.e., layers from the electron transit layer 4 up to the passivation film 14) are laid up in the order illustrated in FIG. 2. FIG. 4 illustrates a cross-sectional diagram of a sample 24 in which layers from the electron transit layer 4 of the semiconductor device 2 up to its cap layer 10 plus its passivation film 14 are laid up in the order illustrated in FIG. 2.

A measurement of the sheet resistance of sample 22 and sample 24 reveals that the sheet resistance of sample 22 that includes the nitrosyl insulating film 12 is higher than the sheet resistance of the sample 24 that lacks the nitrosyl insulating film 12. The lower the two-dimensional electron gas density, the higher the sheet resistance is. Therefore, the fact that the sheet resistance of sample 22 that includes the nitrosyl insulating film 12 is higher than the sheet resistance of the sample 24 that lacks the nitrosyl insulating film 12 indicates that the two-dimensional electron gas density drops on account of the nitrosyl insulating film 12.

Passivation Film 14

The semiconductor device 2 (see FIG. 2) further includes the passivation film 14 that covers the source electrode S, the drain electrode D, the cap layer 10 and the nitrosyl insulating film 12. The passivation film 14 is, for instance, of silicon nitride (i.e., SiN).

The source electrode S is connected to, for instance, an electrode pad (not depicted) disposed on or above the passivation film 14 via wiring not depicted. The same is true of the drain electrode D and the gate electrode G.

Shape of the Gate Electrode G

In the example illustrated in FIG. 2, the gate electrode G includes a lower portion 16 (hereafter referred to as gate lower portion) and an upper portion 20 (hereafter referred to as gate upper portion) that is disposed on or above the gate lower portion 16. The upper portion 20 extends towards the source electrode S and towards the drain electrode D. That is, the gate electrode G is a mushroom-shaped gate electrode. This structure allows reducing the width of the gate lower portion 16 (i.e., gate length) and thereby increasing operating speed. Furthermore, this structure allows increasing the width of the gate upper portion 20 and thereby reducing the resistance of the gate electrode G.

In a case where the gate electrode G has a mushroom-shaped gate electrode, preferably, at least one end of the nitrosyl insulating film 12 may be disposed between the gate upper portion 20 and the electron supply layer 6 (see FIG. 2). Both ends of the nitrosyl insulating film 12 (i.e., the entirety of the nitrosyl insulating film 12) may be disposed between the gate upper portion 20 and the electron supply layer 6.

However, the gate upper portion 20 may extend toward just one from among the source electrode S and the drain electrode D. Alternatively, the gate electrode G may be a rectangular electrode in which the widths of the gate upper portion 20 and the gate lower portion 16 are identical.

(2) Operation

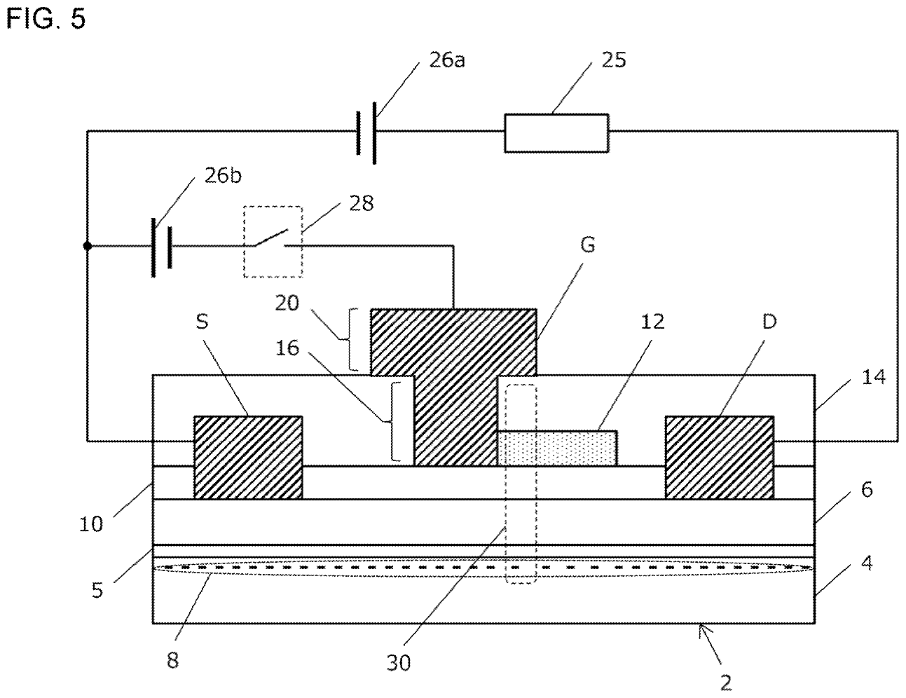

FIG. 5 is a diagram for explaining the operation of the semiconductor device 2. A DC power supply 26a (hereafter referred to as drain power supply) is connected between the source electrode S and the drain electrode D of the semiconductor device 2, for instance, across a load 25. Another DC power supply 26b (hereafter referred to as gate power supply) is connected between the source electrode S and the gate electrode G, for instance, via a switch 28.

A voltage Vds across the drain electrode D and the source electrode S (hereafter referred to as drain-source voltage) is voltage (=E_{D}−V_{L}>0) that results from subtracting the voltage V_{L} (≥0) generated across the load 25 from an electromotive force E_{D} (>0) of the drain power supply 26a. The potential of the drain electrode D is herein positive, taking the potential of the source electrode S as a reference potential.

A voltage Vgs across the gate electrode G and the source electrode S (hereafter referred to as gate-source voltage) is approximately 0 V while the switch 28 is open. While the switch 28 is closed, the gate-source voltage Vgs is approximately equal to a negative voltage (=−E_{G}<0) the absolute value of which is the electromotive force E_{G} (>0) of the gate power supply 26b. The potential of the gate electrode G is approximately 0 V or negative, taking the potential of the source electrode S as the reference potential.

The two-dimensional electron gas 8 spreads from underneath the source electrode S up to underneath the drain electrode D, in the electron transit layer 4, while the switch 28 is open and the gate-source voltage Vgs is kept at approximately 0 V. Electrons in the two-dimensional electron gas 8 can therefore flow from the source electrode S towards the drain electrode D. In other words, the semiconductor device 2 turns on (i.e., conducts) when the switch 28 opens.

When the switch 28 closes and the gate-source voltage Vgs becomes negative, the two-dimensional electron gas 8 breaks off underneath the gate electrode G. The electrons in the two-dimensional electron gas 8 fail thereupon to flow from the source electrode S to the drain electrode D. In other words, the semiconductor device 2 turns off (i.e., becomes non-conductive) when the switch 28 closes. That is, the semiconductor device 2 is a normally-on HEMT.

(3) Improvement of Withstand Voltage

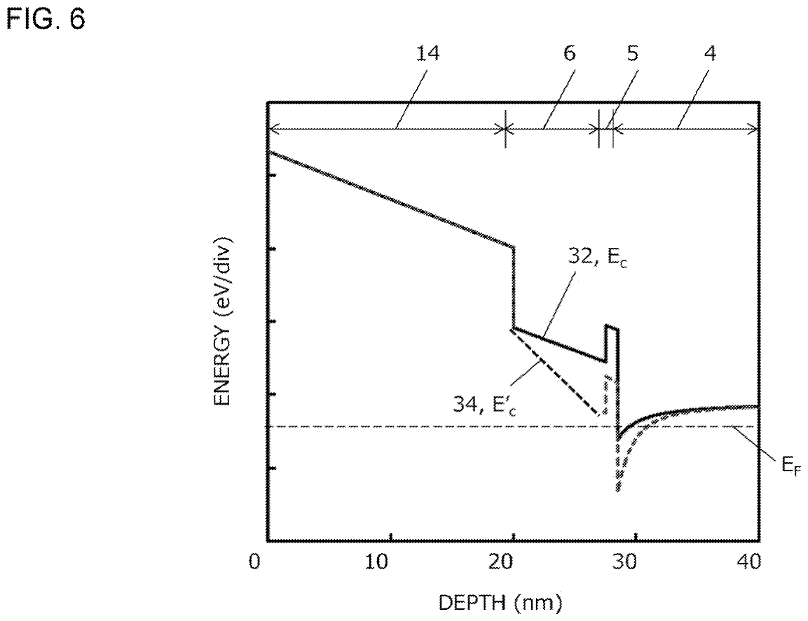

FIG. 6 illustrates an example of a band diagram of the semiconductor device 2 at a region (hereafter referred to as gate edge region) positioned below an overhang portion at which the gate upper portion 20 (see FIG. 5) juts from the gate lower portion 16. FIG. 5 depicts a gate edge region 30 located on the drain electrode side. The vertical axis is electron energy. The horizontal axis is depth measured from the surface of the passivation film 14.

The solid line 32 in FIG. 6 denotes energy Ec at the bottom of the conduction band of the semiconductor device 2. The dashed line 34 in FIG. 6 denotes energy Ec′ at the bottom of the conduction band of an HEMT not having the nitrosyl insulating film 12 (hereafter referred to as nitrosyl film-less HEMT). The structure of nitrosyl film-less HEMT is approximately the same as the structure of the semiconductor device 2, except for not having the nitrosyl insulating film 12. FIG. 6 does not depict the energy at the bottom of the conduction band of the cap layer 10 and of the nitrosyl insulating film 12. However, the cap layer 10 and the nitrosyl insulating film 12 are also mentioned in the explanation that follows.

The solid line 32 and the dashed line 34 respectively denote energy Ec, Ec′ at the bottom of the conduction band when the gate-source voltage Vgs and the drain-source voltage Vds are 0 V. The double-headed arrows at the top of FIG. 6 denote the ranges occupied by each layer (for instance the electron transit layer 4) of the semiconductor device 2. A reference symbol (for instance “4”) adjoined to a double-headed arrow is the reference symbol of the layer (for instance “electron transit layer”) located in the range denoted by the double-headed arrow.

As illustrated in FIG. 6, at the uppermost portion of the electron transit layer 4, which is in contact with the spacer layer 5, the energies Ec and Ec′ at the bottom of the conduction band are lower than the Fermi level E_{F}. Thus, the two-dimensional electron gas 8 is generated (i.e., induced) therein.

As illustrated in FIG. 6, energies Ec, Ec′ at the bottom of the conduction band are sloped for all of the spacer layer 5, the electron supply layer 6, the cap layer 10 (not depicted), the nitrosyl insulating film 12 (not depicted) and the passivation film 14. Therefore, although an electric field is generated in all of these regions, attention will however be devoted herein to the electric field (hereafter referred to as gate edge electric field) generated in the electron supply layer 6 and so forth (specifically the spacer layer 5, the electron supply layer 6 and the cap layer 10) within the gate edge region 30.

Inducement of the two-dimensional electron gas 8 is suppressed by the nitrosyl insulating film 12 in the semiconductor device 2 of the embodiment, as described above. In other words, the two-dimensional electron gas density of the semiconductor device 2 is lower under the the nitrosyl insulating film 12 than the two-dimensional electron gas density of a nitrosyl film-less HEMT. As a result, the gate edge electric field of the semiconductor device 2 is weaker than the gate edge electric field of a nitrosyl film-less HEMT, as made apparent by the difference in the slopes of the solid line 32 and of the dashed line 34.

The gate edge electric field generated when the gate-source voltage Vgs and the drain-source voltage Vds are 0 V will be referred to herein as built-in electric field. Using this terminology, the findings explained with reference to FIG. 5 and FIG. 6 can be summarized in that the built-in electric field of the semiconductor device 2 is weaker than the built-in electric field of a nitrosyl film-less HEMT.

In the above explanation, the gate-source voltage Vgs and drain-source voltage Vds are 0 V. However, while the semiconductor device 2 is in operation, the drain power supply 26a (see FIG. 5) is connected between the source electrode S and the drain electrode D of the semiconductor device 2. Thus, the drain-source voltage Vds is not 0 V while the semiconductor device 2 is in operation.

When the switch 28, which is connected to the gate electrode G, is opened, the semiconductor device 2 turns on (see “(2) Operation”). Thereupon, voltage V_{L} is generated across the load 25 by the current that flows in the load 25, and the drain-source voltage Vds becomes approximately 0 V. Therefore, the explanation above expounded with reference to FIG. 5 and FIG. 6 holds approximately while the switch 28 is open.

When by contrast the switch 28 is closed, negative voltage (=−E_{G}) is applied to the gate electrode G. Thus, the two-dimensional electron gas 8 disappears underneath the gate electrode G. Thereupon, the semiconductor device 2 turns off, and virtually no current flows any longer in the load 25. As a result, the drain-source voltage Vds becomes approximately equal to the electromotive force E_{D} of the drain power supply 26a.

Moreover, as a result of the disappearance of the two-dimensional electron gas 8 underneath the gate electrode G, the electron transit layer 4 between the drain electrode D and the gate electrode G (i.e., the electron transit layer 4 on the drain electrode side) becomes electrically disconnected from the electron transit layer 4 between the source electrode S and the gate electrode G. Therefore, when the switch 28 is closed, voltage that is approximately equal to the electromotive force E_{D} of the drain power supply 26a is applied to the electron transit layer 4 on the drain electrode side. In consequence, a great voltage approximately equal to the total (=E_{G}+E_{D}) of the electromotive force E_{G} of the gate power supply 26b and the electromotive force E_{D} of the drain power supply 26a is applied to the gate edge region 30, which is on the drain side.

As a result, a great electric field (hereafter referred to as external electric field) is generated in the electron supply layer 6 and so forth within the gate edge region 30. The orientation of the external electric field is the same as the orientation of the built-in electric field explained with reference to FIG. 6. Thus, when the switch 28 is closed, an external electric field becomes superimposed on the built-in electric field so that the gate edge electric field increases (i.e., the electric field becomes concentrated). The electron supply layer 6 and so forth readily undergo dielectric breakdown as a result. When the two-dimensional electron gas density is raised in order to increase current, the built-in electric field grows, and hence dielectric breakdown becomes yet likelier in the electron supply layer 6 and so forth.

As pointed out above, the built-in electric field of the semiconductor device 2 is much weaker than the built-in electric field of a nitrosyl film-less HEMT. Therefore, the gate edge electric field generated in the semiconductor device 2 upon closing of the switch 28 (i.e., the gate edge electric field during an on-operation) is weaker than the gate edge electric field generated by a nitrosyl film-less HEMT upon closing of the switch 28. Dielectric breakdown of the electron supply layer 6 and so forth can hence be suppressed by the semiconductor device 2 of the embodiment.

The operating current of an HEMT decreases when the two-dimensional electron gas density drops. Although the nitrosyl insulating film 12 reduces the two-dimensional electron gas density, the nitrosyl insulating film 12 is disposed in only a portion between the gate electrode G and the drain electrode D, and hence the decrease in HEMT operating current due to the nitrosyl insulating film 12 is limited.

(4) Reproducibility of Withstand Voltage

The withstand voltage of the nitride semiconductor HEMT can be increased also by an insulating film (for instance an AlOₓ film) other than the nitrosyl insulating film 12. As explained below, however, it is difficult to increase the withstand voltage of the nitride semiconductor HET by an insulating film (hereafter referred to as non-nitrosyl insulating film) other than the nitrosyl insulating film 12, with favorable reproducibility.

For instance, the two-dimensional electron gas density of the electron transit layer 4 decreases also when an AlOₓ film (where x>1.5, likewise hereafter) is disposed on or above the electron supply layer 6. However, the two-dimensional electron gas density reduced by the AlOₓ film easily approaches the original two-dimensional electron gas density through heating of the AlOₓ film. Moreover, it is difficult to accurately control the change of the two-dimensional electron gas density due to the heating of the AlOₓ film.

The semiconductor device 2 is formed as a result of a process that involves heating the nitrosyl insulating film 12 (see “(5) Production method”). It is therefore difficult to control the two-dimensional electron gas density at the gate edge region 30 (see FIG. 5) on the drain electrode side when disposing an AlOₓ film instead of the nitrosyl insulating film 12. It is accordingly difficult to improve the withstand voltage of the nitride semiconductor HEMT, with favorable reproducibility, by disposing the AlOₓ film. The same is true of non-nitrosyl insulating films (for instance a SiN_{y} film) other than an AlOₓ film.

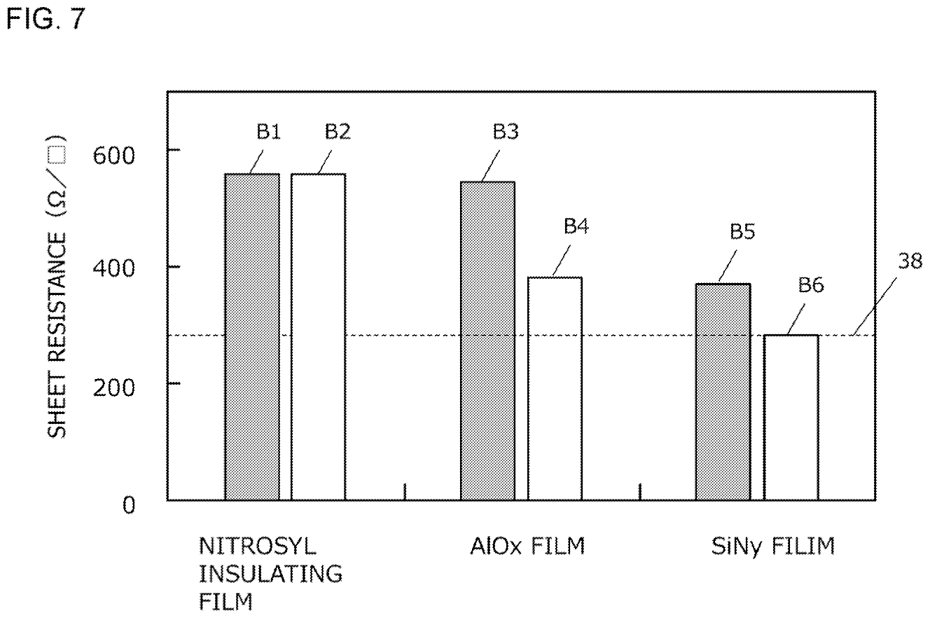

FIG. 7 is a diagram illustrating the influence that the type of insulating film disposed on or above the electron supply layer 6 exerts on the sheet resistance of the electron transit layer 4. The vertical axis is the sheet resistance of the electron transit layer 4. The horizontal axis is the type of the insulating film disposed on or above the electron supply layer 6.

The first insulating film from the left is a nitrosyl insulating film. The second insulating film from the left (i.e., AlOₓ film) is Al₂O₃ with an excess of oxygen relative to the stoichiometric composition (i.e., AlOₓ film where x>1.5). The third insulating film from the left (i.e., SiN_{y} film) is Si₃N₄ with an excess of nitrogen relative to the stoichiometric composition (i.e., SiN_{y} film where y>4/3). The AlOₓ film and the SiN_{y} film are concrete examples of non-nitrosyl insulating films.

The AlOₓ film having the sheet resistance illustrated in FIG. 7 is formed as a result of a thermal treatment, in an oxygen atmosphere, of an Al₂O₃ film formed by ALD (Atomic Layer Deposition). The temperature of the thermal treatment is for instance 600° C. to 1000° C. (herein 750° C.). The duration of the thermal treatment is 1 minute. The SiN_{y} film having the sheet resistance illustrated in FIG. 7 is formed by plasma CVD (Plasma-Chemical Vapor Deposition) with supply of excess ammonia. The nitrosyl insulating film having the sheet resistance illustrated in FIG. 7 is a nitrosyl-oxynitride film 44 (see “(5)” Production method”). The thickness of each insulating film (i.e., the nitrosyl insulating film, the AlOₓ film and the SiN_{y} film) is 10 nm.

The structure of each sample (hereafter referred to as measurement sample) in FIG. 7, for which the sheet resistance has been measured, is approximately identical to that of sample 22 explained with reference to FIG. 3. The insulating film (for instance AlOₓ film) disposed on or above the cap layer 10 is an insulating film notated along the horizontal axis in FIG. 7. The passivation film 14 is not provided in the measurement sample, in order to avoid the impact of heating that accompanies formation of the passivation film 14.

Each gray bar graph is the sheet resistance of the electron transit layer 4 in a respective measurement sample that is not heated after the insulating film (for instance, a nitrosyl insulating film) is arranged. Each white bar graph is the sheet resistance of the electron transit layer 4 in a respective measurement sample that is heated after an insulating film (for instance a nitrosyl insulating film) is arranged. The dashed line 38 denotes the sheet resistance of a sample (hereafter referred to as comparative sample) in which no insulating film is arranged on or above the electron supply layer 6.

The structure and production conditions of the electron supply layer 6 and so forth are described in “(5) Production method”. The heating temperature of the measurement samples is 300° C., and the heating time is 1 to 2 hours. The heating temperature and heating time are the same as the film formation temperature and film formation time of the passivation film 14.

As illustrated in FIG. 7, the sheet resistance of the electron transit layer 4 increases (see third bar graph B3 from the left in FIG. 7) also by arranging (i.e., forming) an AlOₓ film on or above the electron supply layer 6. When the measurement sample having the AlOₓ film disposed on or above the the electron supply layer 6 is heated, however, the sheet resistance of the electron transit layer 4 decreases (see fourth bar graph B4 from the left in FIG. 7).

The decrease in two-dimensional electron gas density translates into in an increase of the sheet resistance of the electron transit layer 4. FIG. 7 reveals therefore that although the two-dimensional electron gas density can be reduced also by an AlOₓ film, the two-dimensional electron gas density reduced thereby comes however close to the original two-dimensional electron gas density on account of heating of the AlOₓ film. The term “original two-dimensional electron gas density” denotes the two-dimensional electron gas density of the comparative sample in which no AlOₓ film or the like is disposed on or above the electron supply layer 6. Moreover, it is difficult to control the change of the two-dimensional electron gas density due to the heating of the AlOₓ film. In the case of a SiN_{y} film, the two-dimensional electron gas density reduced by virtue of the SiN_{y} film returns to the original two-dimensional electron gas density as a result of heating (see the fifth and sixth bar graphs B5, B6 from the left in FIG. 7).

The AlOₓ film having excess oxygen includes numerous dangling bonds of oxygen atoms. When the dangling bonds capture electrons and the AlOₓ film becomes negatively charged thereby, the polarization of the electron supply layer 6 weakens, and the two-dimensional electron gas density decreases as a result.

When the AlOₓ film is heated, however, the dangling bonds decreases easily, for instance through bonding with other dangling bonds. Therefore, the negative charge of the AlOₓ film decreases when the AlOₓ film is heated. Moreover, it is difficult to control the decrement in negative charge of the AO film. The same is true of a SiN_{y} film having an excess of nitrogen atoms. The nitrogen atoms in the SiN_{y} film become negatively charged through capture of electrons by the dangling bonds of the nitrogen atoms.

As described above, the two-dimensional electron gas density of the electron transit layer 4 drops when an AlOₓ film is arranged on or above the electron supply layer 6. However, the lowered two-dimensional electron gas density easily approaches the original two-dimensional electron gas density, through heating of the AlOₓ film. Moreover, it is difficult to control the change of the two-dimensional electron gas density due to the heating of the Ala film.

The same is true of the SiN_{y} film.

As illustrated in FIG. 7, by contrast, the sheet resistance increased as a result of arranging the nitrosyl insulating film on or above the electron supply layer 6 does not vary even when the nitrosyl insulating film is heated (see first and second bar graphs B1, B2 from the left in FIG. 7). That is, the two-dimensional electron gas density decreases when the nitrosyl insulating film is disposed on or above the electron supply layer 6, and this lowered two-dimensional electron gas density does not increase or decrease even when the nitrosyl insulating film is heated.

The withstand voltage of the nitride semiconductor HEMT can therefore be improved, with favorable reproducibility, by the nitrosyl insulating film 12. In addition, the decrement in two-dimensional electron gas density derived from the nitrosyl insulating film 12 is greater than the decrement in two-dimensional electron gas density derived from the heated AlOₓ film. The withstand voltage of the nitride semiconductor HEMT is hence increased to a greater degree by the nitrosyl insulating film 12 than by the AlOₓ film. The heated SiN_{y} film virtually has no ability to increase the withstand voltage of the nitride semiconductor HEMT.

In a same manner to AlOₓ, the nitrosyl group (i.e., —N═O) includes an oxygen atom that may constitute a supply source of dangling bonds. Moreover, the nitrosyl group includes a nitrogen atom that may constitute a supply source of dangling bonds, in a same manner to the SiN_{y} film.

The oxygen atom and the nitrogen atom of the nitrosyl group are however firmly bonded to each other by a double bond, and accordingly neither atom can constitute a supply source of dangling bonds. It is therefore deemed that the reduced two-dimensional electron gas density does not drop even if the nitrosyl insulating film is heated.

(5) Production Method

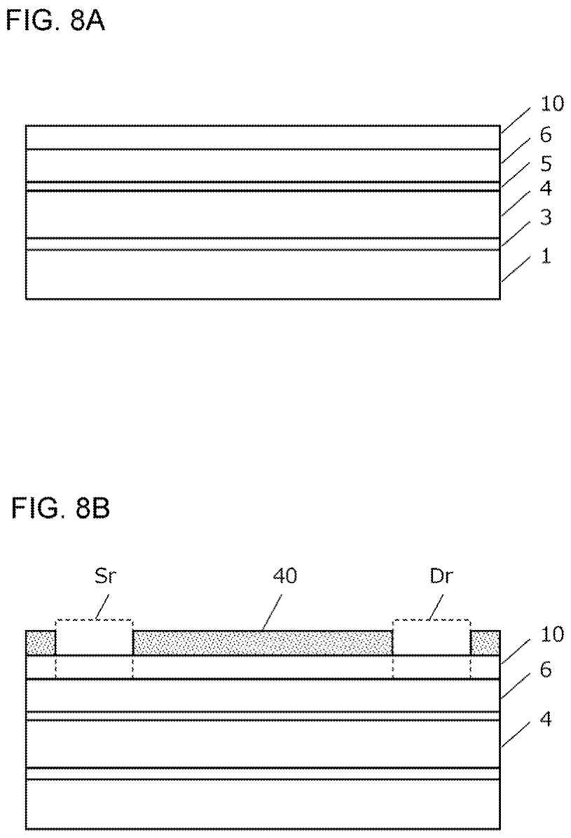

FIG. 8A to FIG. 12B are cross-sectional diagrams illustrating an example of a production method of the semiconductor device 2 in the embodiment.

(5-1) Formation of Layers from the Electron Transit Layer 4 to the Cap Layer 10 (see FIG. 8A)

A buffer layer 3 (specifically for instance an AlGaN layer) and the electron transit layer 4 (specifically for instance an i-type GaN layer) are grown in this order, for instance by MOVPE (Metal Organic Vapor Phase Epitaxy), on or above a SIC substrate 1 (see FIG. 8A). Further, the spacer layer 5 (specifically for Instance an i-type AlGaN layer) and the electron supply layer 6 (specifically for instance an n-type AlGaN layer) are grown by MOVPE on or above the electron transit layer 4. Lastly, the cap layer 10 (specifically for instance an n-type GaN layer) is grown by MOVPE on the electron supply layer 6 (see FIG. 8A).

Any one from among a GaN substrate, an AlN substrate and a Si substrate can be used instead of the SIC substrate 1. Formation of the cap layer 10 may be omitted.

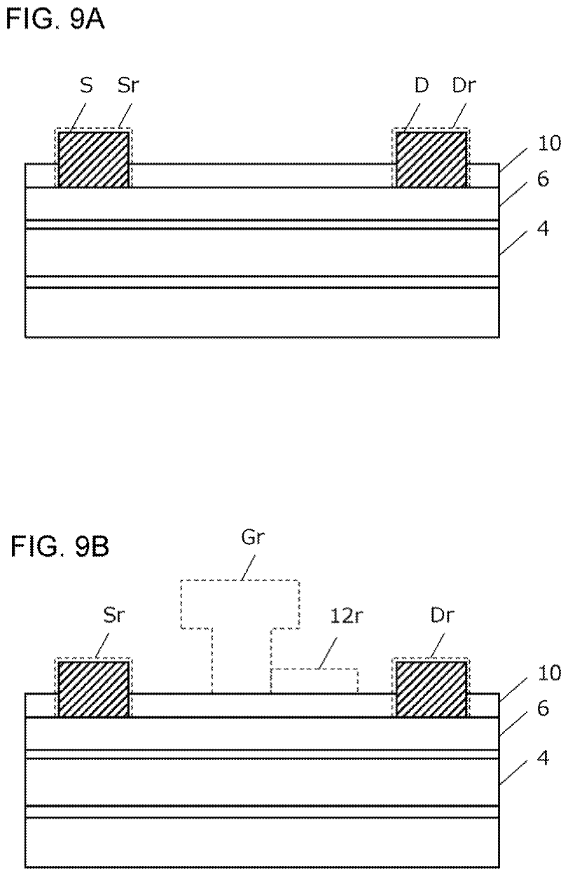

(5-2) Formation of the Source Electrode S and the Drain Electrode D (see FIG. 88 and FIG. 9A)

Formed on the cap layer 10 by means of photolithography is a resist film 40 that includes openings in a source electrode region Sr (see FIG. 8B) and a drain electrode region Dr. The source electrode region Sr is a region on the electron supply layer 6. The drain electrode region Dr is a region on the electron supply layer 6 and alongside of the source electrode region Sr.

The cap layer 10 within the source electrode region Sr and within the drain electrode region Dr is selectively removed by dry etching to expose the electron supply layer 6 there, using the resist film 40. The etching gas is a chlorine-based gas (for instance Cl₂ gas or BCl₃ gas).

Thereafter a titanium layer and an aluminum layer are deposited, in this order, on the exposed portion of the electron supply layer 6 and the resist film 40, to thereby form a Ti/Al film. The Ti/Al film is removed on the resist film 40 together with the resist film 40, to thereby form Ti/Al layers in the source electrode region Sr and in the drain electrode region Dr.

Thereafter, the Ti/Al layers are heated at a temperature between 400° C. and 1000° C. in a nitrogen atmosphere. The source electrode S having an ohmic characteristic becomes formed from the Ti/Al layer within the source electrode region Sr, as a result of this heating treatment (see FIG. 9A). Further, the drain electrode D having an ohmic characteristic becomes formed from the Ti/Al layer within the drain electrode region Dr.

(5-3) Formation of the Nitrosyl Insulating Film 12 (See FIGS. 9B to 10B and FIGS. 13 to 15)

After formation of the source electrode S and the drain electrode D, the nitrosyl insulating film 12 (see FIG. 2) is formed in a nitrosyl region 12r (see FIG. 9B) on the cap layer 10. The nitrosyl region 12r is a region positioned between the gate electrode region Gr (see FIG. 9B) and the drain electrode region Dr. Moreover, the nitrosyl region 12r is a region closer to the gate electrode region Gr than to the drain electrode region Dr. The gate electrode region Gr is a region on the cap layer 10. Moreover, the gate electrode region Gr is a region positioned between the source electrode region Sr and the drain electrode region Dr. In a case where the cap layer 10 is omitted, the gate electrode region Gr is a region on the electron supply layer 6 (the same is true of the nitrosyl region 12r). The thickness of the nitrosyl insulating film 12 is 5 to 20 nm (for instance 10 nm).

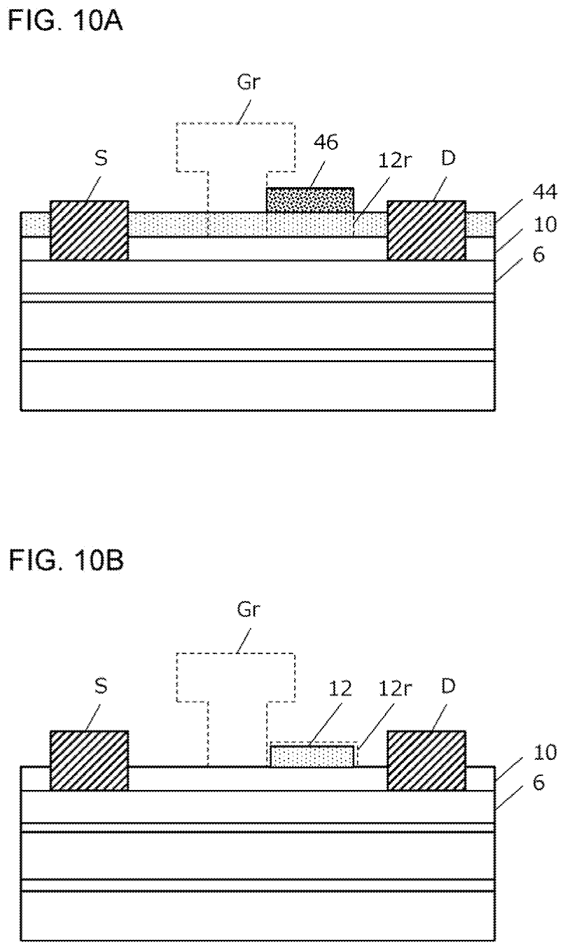

The nitrosyl insulating film 12 is formed in accordance with the procedure below. Firstly, formed on the cap layer 10 (see FIG. 10A) is a thin film 44 of aluminum oxynitride that includes nitrosyl groups (hereafter referred to as nitrosyl-oxynitride film). A resist film 46 that covers the nitrosyl region 12r is formed, by photolithography, on the nitrosyl-oxynitride film 44.

The nitrosyl-oxynitride film 44 is removed in regions not covered by the resist film 46 by wet etching, and thereafter the resist film 46 is removed, to thereby form the nitrosyl insulating film 12 in the nitrosyl region 12r (see FIG. 10B). The etching solution is for instance an alkaline solution, e.g., TMAH (tetramethyl ammonium hydroxide).

Formation of the Nitrosyl-Oxynitride Film

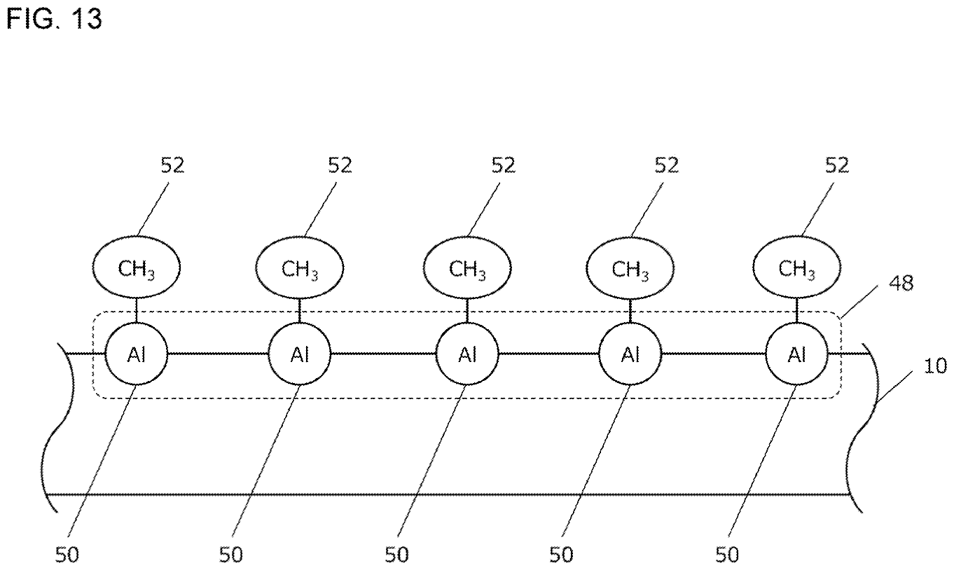

FIGS. 13 to 15 are diagrams illustrating an example of a procedure for forming the nitrosyl-oxynitride film 44 (see FIG. 10A). Firstly, a monoatomic layer 48 of Al (hereafter referred to as Al atom layer) is formed, by ALD, on the cap layer 10 (see FIG. 13). The feedstock gas used for growing the Al atom layer 48 is for instance trimethylaluminum.

Herein Al atoms are group-III atoms, and accordingly include five bonds. Herein Al atoms 50 in the Al atom layer 48 are bonded to the cap layer 10 by some of the five bonds. The Al atoms 50 are bonded to methyl groups 52 (i.e., —CH₃) by the remaining bonds. The methyl groups 52 are functional groups derived from trimethylaluminum.

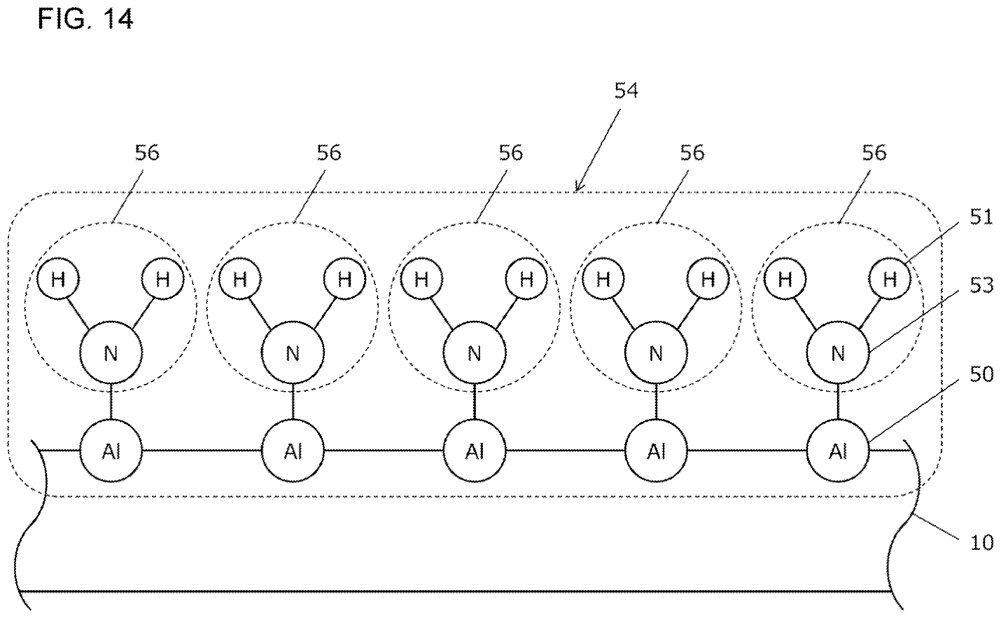

Aluminum nitride 54 (see FIG. 14) including hydrogen atoms 51 (i.e., aluminum nitride that includes nitrogen atoms 53 bonded to the hydrogen atoms 51) becomes formed on the cap layer 10 through supply of for instance NH₃ gas to the Al atom layer 48. In this reaction, the NH₃ gas reacts with the methyl groups 52 (see FIG. 13) and turns into amino groups 56 (see FIG. 14) and methane (i.e., CH₄) gas.

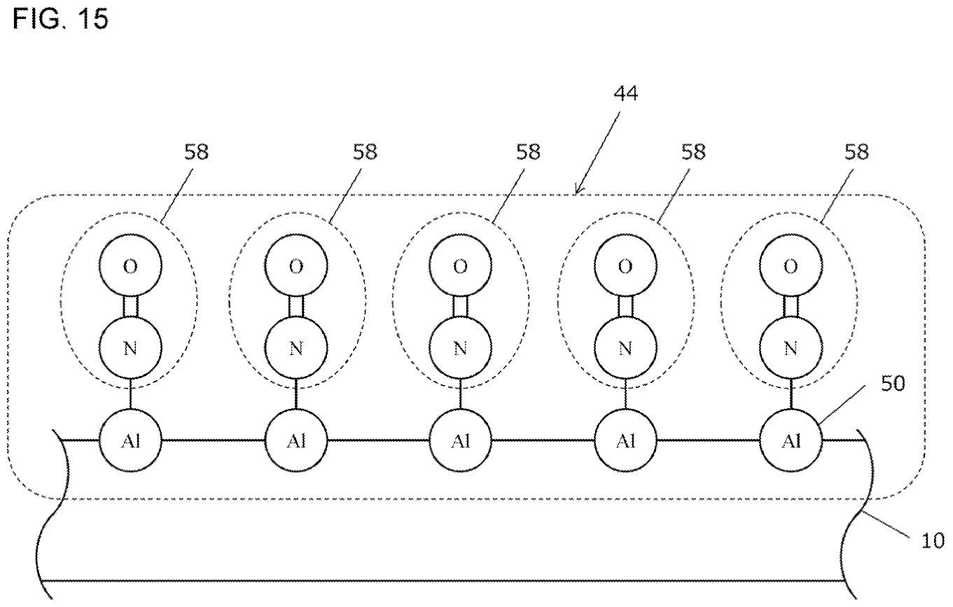

The nitrogen atoms 53 of the amino groups 56 bond to the Al atoms 50 by one of three bonds, to thereby form a skeleton of the aluminum nitride 54. The remaining bonds of the nitrogen atoms 53 are bonded to the H atoms 51. The H atoms 51 derive from the NH₃ gas. Thereafter, the aluminum nitride 54 is oxidized by hydroxyl radicals (i.e., OH*), to thereby form the nitrosyl-oxynitride film 44 (see FIG. 15).

In the oxidation reaction of the aluminum nitride 54, the hydroxyl radicals react with the amino groups 56 (see FIG. 14), to elicit change from them into nitrosyl groups 58 (see FIG. 15) and hydrogen molecules.

The hydroxyl radicals are generated for instance through irradiating water vapor with ultraviolet rays. Specifically, hydroxyl radicals are generated upon irradiation of water vapor with ultraviolet rays having intensity in a wavelength range of 250 nm or shorter. Herein nitrosyl groups decompose when irradiated with ultraviolet rays having intensity in a wavelength range from 140 nm to 150 nm. Therefore, the ultraviolet rays with which the water vapor is irradiated may preferably have intensity in the wavelength range from 150 nm to 250 nm. The wording “having intensity in a wavelength range” signifies herein that light intensity per unit wavelength in a given wavelength range is greater than zero.

Such ultraviolet rays can be generated for instance by allowing the output light of a mercury lamp to pass through a filter that transmits light having a wavelength of 250 nm or shorter. Ultraviolet rays with intensity in a wavelength range from 150 nm to 250 nm can be generated also by an excimer lamp.

In the examples illustrated in FIGS. 14 to 15, all the amino groups 56 are converted to nitrosyl groups 58. However, it suffices herein that some of the amino groups 56 is converted to nitrosyl groups 58. When trimethylaluminum is supplied again to such a nitrosyl-oxynitride film 44, the Al atom layer 48 (see FIG. 13) is re-formed through reaction of the trimethylaluminum with unreacted amino groups 56. A nitrosyl-oxynitride film 44 that includes a plurality of Al atom layers 48 and a plurality of nitrogen atom layers can be formed thereupon, since the reactions explained with reference to FIGS. 14 to 15 can take place again.

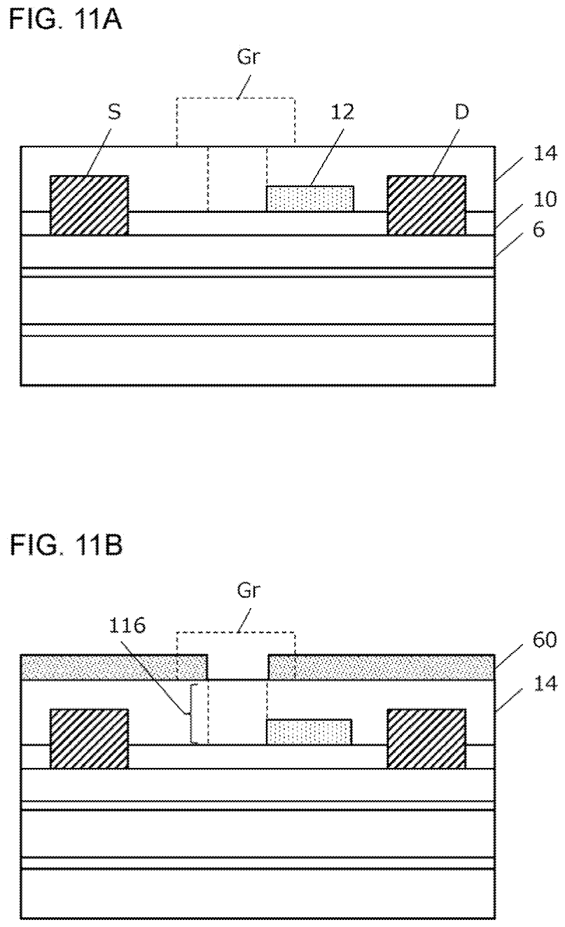

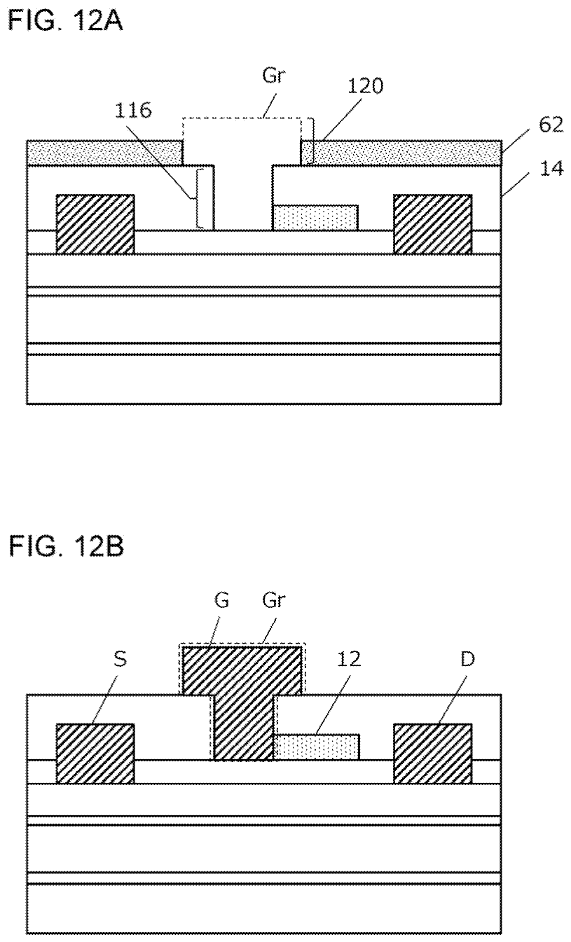

(5-4) Formation of the Gate Electrode G (See FIGS. 11A to 12B)

The passivation film 14 (specifically for instance a SiN film) that covers the source electrode S, the drain electrode D, the nitrosyl insulating film 12 and the cap layer 10 is formed for instance by plasma CVD (see FIG. 11A). The thickness of the passivation film 14 is 10 to 100 nm (for instance 40 nm).

A resist film 60 that surrounds a lower portion 116 (hereafter referred to as gate lower region) of the gate electrode region Gr in a plan view is formed, by photolithography, on the passivation film 14 (see FIG. 118). The passivation film 14 within the gate lower region 116 is removed by dry etching, using the resist film 60. The etching gas is for instance a fluorine-based gas.

Thereafter, the resist film 60 is removed, and a resist film 62 that has an opening in an upper portion 120 (hereafter referred to as gate upper region) of the gate electrode region Gr is formed on the passivation film 14 (see FIG. 12A).

Thereafter, a nickel film and an Au film are deposited, in this order, in the interior of the gate electrode region Gr and on the resist film 62, to form a Ni/Au film. The formed Ni/Au film is removed on the resist film 62 together with the resist film 62, to form the gate electrode G (herein an Ni/Au layer) in the gate electrode region Gr (see FIG. 128). The semiconductor device 2 becomes thus formed as a result of the above process.

In the present embodiment, the nitrosyl insulating film 12 is disposed in the vicinity of the drain-side gate edge. As a result, the two-dimensional electron gas density can be controlled accurately in the vicinity of the drain-side gate edge, and hence the withstand voltage of the nitride semiconductor HEMT can be increased with favorable reproducibility.

An embodiment of the present invention has been explained above, but the embodiment is illustrative and not meant to be restrictive in any way. For instance, the nitrosyl insulating film 12 in the embodiments is of aluminum oxynitride that includes nitrosyl groups. However, the nitrosyl insulating film 12 is not limited to aluminum oxynitride that includes nitrosyl groups.

The nitrosyl insulating film 12 may be any from among, for instance, hafnium oxynitride that includes nitrosyl groups, silicon oxynitride that includes nitrosyl groups, and gallium oxynitride that includes nitrosyl groups. Alternatively, the nitrosyl insulating film 12 may be any from among indium oxynitride that includes nitrosyl groups, titanium oxynitride that includes nitrosyl groups, tantalum oxynitride that includes nitrosyl groups, and nickel oxynitride that includes nitrosyl groups.

In the usage example illustrated in the embodiment, the semiconductor device 2 is used as a switch element (see “(2) Operation”). However, the semiconductor device 2 may be used as an element other than a switch element. The semiconductor device 2 may be used for instance as an amplification element.

In the embodiment, the gate electrode G is formed after formation of the source electrode S and the drain electrode D. However, the order in which the gate electrode G is formed is not limited to such an order. The gate electrode G may be formed for instance before the source electrode S and the drain electrode D are formed. The same is true of the order in which the nitrosyl insulating film 12 is formed. Specifically, the order in which the source electrode S, the drain electrode D, the gate electrode G and the nitrosyl insulating film 12 are formed can be rearranged as appropriate.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed:

1. A semiconductor device, comprising:
an electron transit layer;
an electron supply layer disposed on or above the electron transit layer, the electron supply layer inducing a two-dimensional electron gas in the electron transit layer;
a source electrode disposed on or above the electron supply layer;
a drain electrode disposed on or above the electron supply layer;
a gate electrode disposed on or above the electron supply layer, the gate electrode being positioned between the source electrode and the drain electrode; and
an insulating film that includes a nitrosyl group, the insulating film being disposed in a region that is positioned on or above the electron supply layer and between the gate electrode and the drain electrode, and the region being closer to the gate electrode than to the drain electrode.

2. The semiconductor device according to claim 1, wherein
the insulating film is aluminum oxynitride that includes the nitrosyl group.

3. The semiconductor device according to claim 1, wherein
the insulating film suppresses the inducing of the two-dimensional electron gas by the electron supply layer at a portion of the electron transit layer, the portion touching a bottom of the gate electrode in a plan view.

4. The semiconductor device according to claim 1, wherein
the gate electrode includes a lower portion and an upper portion disposed on or above the lower portion, the upper portion extending at least towards the drain electrode, and
at least one end of the insulating film is disposed between the upper portion and the electron supply layer.

5. A method for producing a semiconductor device, the method comprising:
forming an electron transit layer;
forming an electron supply layer on or above the electron transit layer, the electron supply layer inducing a two-dimensional electron gas in the electron transit layer;
forming a source electrode in a source electrode region that is on or above the electron supply layer;
forming a drain electrode in a drain electrode region that is on or above the electron supply layer;
forming a gate electrode in a gate electrode region that is between the source electrode region and the drain electrode region; and
forming an insulating film in a region on or above the electron supply layer, the the region being positioned between the gate electrode region and the drain electrode region, and the region being closer to the gate electrode region than to the drain electrode region, the insulating film including a nitrosyl group; wherein
the forming of the insulating film is a process in which aluminum nitride that includes nitrogen atoms bonded to hydrogen atoms is formed on or above the electron supply layer, and the formed aluminum nitride is oxidized by hydroxyl radicals.

6. The method for producing a semiconductor device according to claim 5, wherein
the hydroxyl radicals are generated by irradiating water vapor with an ultraviolet ray.

7. The method for producing a semiconductor device according to claim 6, wherein
the ultraviolet ray has intensity in a wavelength range from 150 nm to 250 nm.
